(19) United States
(12) Patent Application Publication
(10) Pub. No.: US 2014/0299869 A1
(43) Pub. Date: Oct. 9, 2014

(54) Organic Electronic Device And Method Of Manufacture

(71) Applicant: CAMBRIDGE DISPLAY TECHNOLOGY LIMITED, Cambridgeshire (GB)

(72) Inventors: Thomas Kugler, Cambridge (GB); Sarah Tyler, Cambs (GB)

(73) Assignee: CAMBRIDGE DISPLAY TECHNOLOGY LIMITED, Cambridgeshire (GB)

(21) Appl. No.: 14/355,577

(22) PCT Filed: Oct. 29, 2012
(86) PCT No.: PCT/GB2012/000816

§ 371 Date: Apr. 30, 2014

(30) Foreign Application Priority Data
Nov. 3, 2011 (GB) 1118997.4
Jan. 26, 2012 (GB) 1201291.0

(51) Int. Cl. H01L 51/00

(52) U.S. Cl. CPC H01L 51/0035; H01L 51/0003; H01L 51/5056
USPC 257/40; 438/99; 438/46

(57) ABSTRACT

A method of forming an organic electronic device comprising the steps of: forming a surface modification layer comprising a partially fluorinated fullerene on at least part of a surface of at least one electrode of the device by depositing a solution comprising the partially fluorinated fullerene and at least one solvent onto the electrode surface; and forming an organic semiconductor layer comprising at least one organic semiconductor on the surface modification layer. The partially fluorinated fullerene is a partially fluorinated Buckminster fullerene, optionally a partially fluorinated C₆₀.

### FIELD OF THE INVENTION

The present invention relates to organic electronic devices having a surface-modified electrode layer, in particular organic light-emitting devices and organic thin-film transistors, and methods of making them.

### BACKGROUND OF THE INVENTION

Organic semiconductors may be used as the active material in a range of devices, including organic light emitting diodes (OLEDs), organic photoresponsive devices (in particular organic photovoltaic devices and organic photosensors) and organic thin-film transistors (OTFTs).

An OLED may comprise a substrate carrying an anode, a cathode and one or more organic light-emitting layers between the anode and cathode. One or more organic charge transporting and/or one or more charge blocking layers may also be provided between the anode and cathode.

Holes are injected into the device through the anode and electrons are injected through the cathode during operation of the device. Holes in the highest occupied molecular orbital (HOMO) and electrons in the lowest unoccupied molecular orbital (LUMO) of a light-emitting material combine to form an exciton that releases its energy as light.

Suitable light-emitting materials include small molecule, polymeric and dendrimeric materials. Suitable light-emitting polymers include poly(arylene vinylenes) such as poly(p-phenylene vinylenes) and polyarylenes such as polyfluorenes.

A light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton) and Appl. Phys. Lett., 2000, 77, 904 discloses a host material doped with a phosphorescent light emitting dopant (that is, a light-emitting material in which light is emitted via decay of a triplet exciton).

An OTFT may comprise source and drain electrodes defining a channel containing an organic semiconductor that is in electrical contact with the source and drain electrodes. A gate electrode is separated from the organic semiconductor by a gate dielectric.

The conductivity of the channel can be altered by the application of a voltage at the gate. In this way the transistor can be switched on and off using an applied gate voltage. The drain current that is achievable for a given voltage is dependent on the mobility of the charge carriers in the organic semiconductor in the active region of the device (the channel region between the source and drain electrodes).

EP 1950818 discloses an organic layer including a fluorine-containing compound between an anode and a hole injection layer of an OLED.

US 2005/0133782 discloses an OTFT comprising a nitrile layer arranged between the source and drain electrodes and the semiconductor. Nitriles disclosed include o-fluorobenzonitrile, p-fluorobenzonitrile, perfluorobenzonitrile and tetracyanoquinodimethane.

US 2010/0203663 discloses an OTFT comprising a thin self-assembled layer on the source and drain electrodes wherein the self-assembled material comprises a dopant moiety for doping an organic semiconductive material and a separate attachment moiety bonded to the dopant moiety and selectively bonded to the source and drain electrodes.

WO 2010/029542 discloses doping of organic semiconductors with fluorinated fullerene dopants by either mixing the dopant and the organic semiconductor in a solution or co-evaporation of the dopant and the organic semiconductor.

A problem to be solved by the invention is to provide a low barrier to charge injection from an electrode to a semiconductor of an organic electronic device.

A further problem to be solved by the invention is to provide a straightforward and controllable method of modifying the surface of an electrode to reduce a charge injection barrier.

### SUMMARY OF THE INVENTION

In a first aspect, the invention provides a method of forming an organic electronic device comprising the steps of:

forming a surface modification layer comprising a partially fluorinated fullerene on at least part of a surface of at least one electrode of the device by depositing a solution comprising the partially fluorinated fullerene and at least one solvent onto the electrode surface; and

forming an organic semiconductor layer comprising at least one organic semiconductor on the surface modification layer.

Optionally, the thickness of the surface modification layer is no more than 10 nm.

Optionally, the surface modification layer is a monolayer.

Optionally, the partially fluorinated fullerene is a partially fluorinated Buckminster fullerene, optionally a partially fluorinated C₆₀.

Optionally, the surface modification layer consists essentially of the partially fluorinated fullerene.

Optionally, the organic semiconducting layer comprises a polymer.

Optionally, the polymer is at least one of the at least one organic semiconductor.

Optionally, the polymer comprises repeat units of formula (XI):

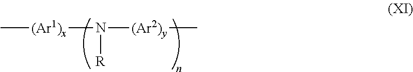

wherein Ar¹ and Ar² in each occurrence are independently selected from unsubstituted or substituted aryl or heteroaryl groups; n is greater than or equal to 1, preferably 1 or 2; R is H or a substituent; any of Ar¹, Ar² and R may be linked by a direct bond or linking group; and x and y are each independently 1, 2 or 3.

Optionally, the polymer comprises one or more unsubstituted or substituted arylene repeat units.

Optionally, the one or more substituted or unsubstituted arylene repeat units are selected from the group consisting of substituted or unsubstituted fluorene repeat units and substituted or unsubstituted phenylene repeat units.

Optionally, the at least one electrode comprises a material having a work function value that is closer to vacuum than a LUMO value of the partially fluorinated fullerene.

In one optional arrangement, the organic electronic device is an organic light-emitting device of which the at least one electrode is an anode, the organic light-emitting device further comprising a cathode and an organic region comprising the organic semiconductor layer between the anode and the cathode.

Optionally, the organic semiconductor layer is an organic light-emitting layer.

Optionally, the organic semiconductor layer is a hole-transporting layer, the organic region further comprising an organic light-emitting layer.

Optionally, the anode is indium-tin oxide.

In another optional arrangement, the organic electronic device is an organic thin-film transistor of which the at least one electrode is a source and drain electrode, the organic thin-film transistor further comprising a channel between the source and drain electrodes wherein the organic semiconductor layer extends across the channel and contacts the surface modification layer; a gate electrode; and a gate dielectric between the organic semiconductor layer and the gate electrode.

Optionally, at least one of the at least one organic semiconductors is selected from compounds of formulae (I)-(V):

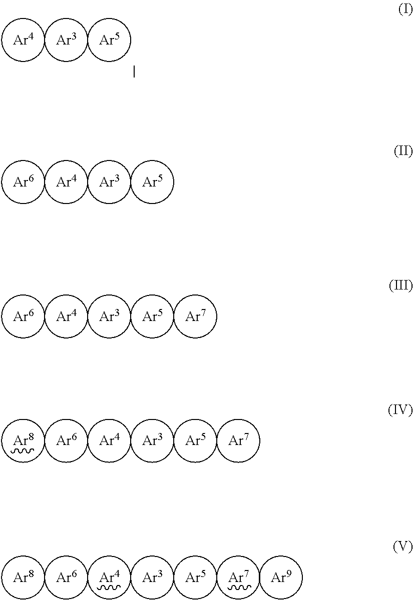

wherein Ar³, Ar⁴, Ar⁵, Ar⁶, Ar⁷, Ar⁸ and Ar⁹ are each independently selected from the group consisting of monocyclic aromatic rings and monocyclic heteroaromatic rings, and wherein Ar³, Ar⁴ and Ar⁵ may each optionally be fused to one or more further monocyclic aromatic or heteroaromatic rings.

Optionally, the organic semiconducting layer further comprises a polymer as described above.

Optionally, the source and drain electrodes are selected from gold, silver, copper and nickel.

Optionally, the surface of at least one of the source and drain electrodes comprises a plurality of faces and wherein the surface modification layer is formed on at least two of the plurality of faces.

Optionally, the surface modification layer is formed on a face of the surface of one or both of the source and drain electrodes that faces the channel.

Optionally, the solution is substantially free of an organic semiconductor doped by the partially fluorinated fullerene.

Optionally, the solution consists essentially of the partially fluorinated fullerene and the at least one solvent.

Optionally, the partially fluorinated fullerene is provided in the solution at a concentration of less than 1 weight %.

In a second aspect the invention provides an organic thin film transistor comprising source and drain electrodes defining a channel therebetween; a surface-modification layer comprising a partially fluorinated fullerene on at least part of the surface of the source and drain electrodes; an organic semiconductor layer extending across the channel and in contact with the surface-modification layer; a gate electrode; and a gate dielectric between the organic semiconductor layer and the gate dielectric.

Optionally according to the second aspect the surface-modification layer is substantially free of any organic semiconductor doped by the partially fluorinated fullerene.

Optionally according to the second aspect the surface-modification layer consists essentially of the partially fluorinated fullerene.

Optionally according to the second aspect the source and drain electrodes are selected from silver, gold, copper, nickel and alloys thereof.

Optionally according to the second aspect the surface modification layer has a thickness of less than 10 nm, and is optionally a monolayer.

Optionally according to the second aspect, the method comprising the steps of:

depositing the partially fluorinated fullerene on the surface of the source and drain electrodes to form the surface modification layer; and

depositing the organic semiconductor on the surface modification layer.

In a third aspect, the invention provides an organic electronic device comprising an organic semiconductor layer in contact with at least one surface modification layer on a surface of at least one electrode of the organic electronic device, wherein the surface modification layer comprises a partially fluorinated fullerene and wherein the thickness of the surface modification layer is no more than 10 nm.

It will be understood that any of the optional method or device features described with reference to the first aspect may be optional features of the second or third aspects.

The invention will now be described in more detail with reference to the drawings in which:

### DESCRIPTION OF THE DRAWINGS

The invention will now be described in more detail with reference to the drawings in which:

FIG. 1A is a schematic illustration of a first OLED according to an embodiment of the invention;

FIG. 1B is a schematic illustration of a second OLED according to an embodiment of the invention;

FIG. 2A is a schematic illustration of a top-gate OTFT according to an embodiment of the invention;

FIG. 2B is a schematic illustration of a bottom-gate OTFT according to an embodiment of the invention;

FIG. 3 shows AC-2 spectra for ITO layers treated with C₆₀F₃₆ or C₆₀F₄₈ and comparative ITO layers untreated with fullerene;

FIG. 4 shows an AC-2 spectrum for a silver layer treated with C₆₀F₃₆;

FIG. 5 shows an AC-2 spectrum for a silver layer treated with C₆₀F₄₈;

FIG. 6 shows an AC-2 spectrum for a gold layer treated with C₆₀F₃₆;

FIG. 7 shows an AC-2 spectrum for a gold layer treated with C₆₀F₄₈;

FIG. 8 shows a graph of current density vs. voltage for devices according to embodiments of the invention and a comparative device; and

FIG. 9 shows a graph of external quantum efficiency vs. voltage for the devices according to embodiments of the invention of FIG. 8.

### DETAILED DESCRIPTION OF THE INVENTION

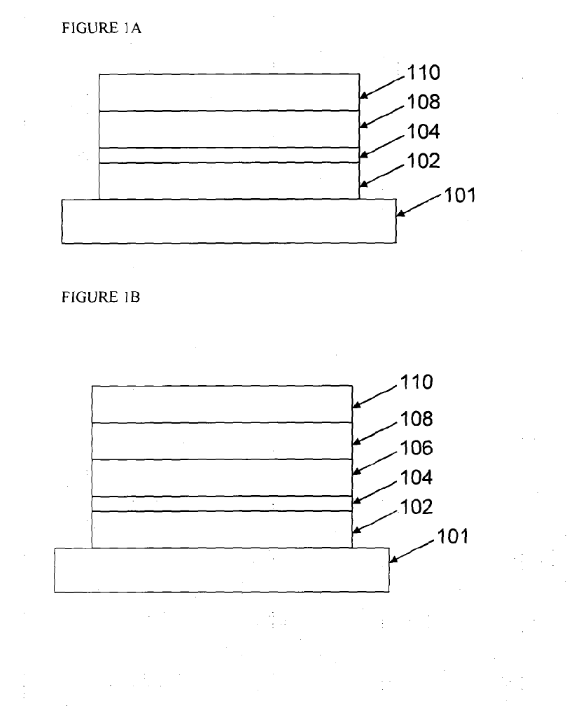

FIG. 1A, which is not drawn to any scale, illustrates schematically an OLED according to an embodiment of the invention. The OLED is carried on substrate 101 and comprises an anode 102, a surface modification layer 104, a cathode 110, and a light-emitting layer 108 comprising an organic semiconducting material between the anode and the cathode.

In the embodiment illustrated in FIG. 1A, the light-emitting layer 108 is in contact with the surface modification layer 104.

The OLED may be provided with one or more additional layers (not shown) between the anode 102 and the cathode 110, including one or more further light-emitting layers and/or one or more charge transporting layers, charge blocking layers and/or exciton blocking layers.

FIG. 1B, which is not drawn to any scale, illustrates schematically an exemplary OLED having a hole-transporting layer 106 and a light-emitting layer 108 between the anode 102 and the cathode 110. In FIGS. 1A and 1B, like reference numerals have been used for corresponding parts. In the OLED of FIG. 1B it is hole-transporting layer 106, rather than light-emitting layer 108, that is in contact with surface modification layer 104.

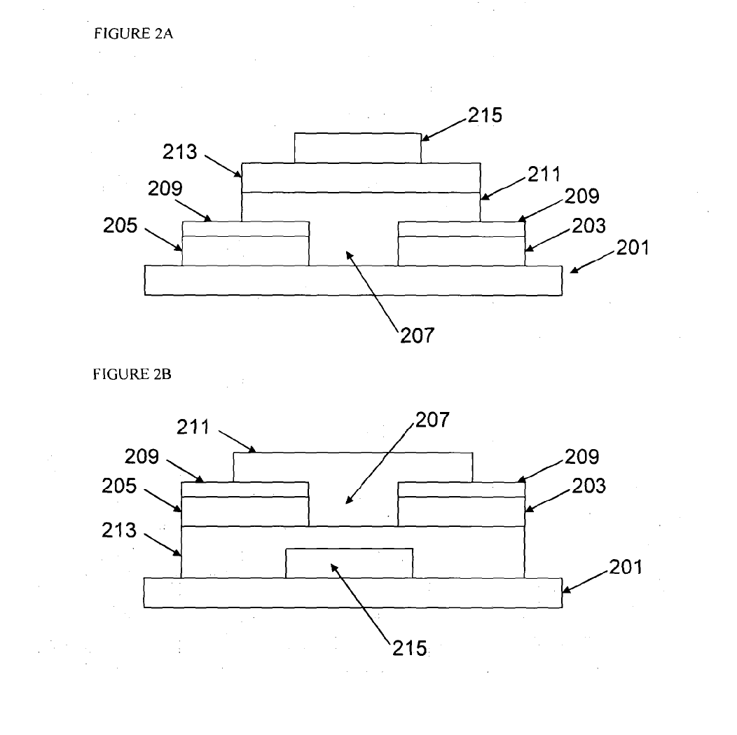

FIG. 2A, which is not drawn to any scale, schematically illustrates an exemplary top-gate organic thin-film transistor. The illustrated structure may be deposited on a substrate 201 and comprises source and drain electrodes 203, 205 which are spaced apart with a channel region 207 located therebetween. The source and drain electrodes 203, 205 carry a surface modification layer 209. An organic semiconductor layer 211 in the channel region 207 is in contact with the surface modification layer 209, and may extend over at least some of the source and drain electrodes 203, 205. An insulating layer 213 of dielectric material is deposited over the organic semi-conductor layer 211 and may extend over at least a portion of the source and drain electrodes 203, 205. Finally, a gate electrode 215 is deposited over the insulating layer 213. The gate electrode 215 is located over the channel region 207 and may extend over at least a portion of the source and drain electrodes 203, 205. Further layers may be provided. For example, the base of the channel region may be treated with an organic material prior to deposition of the organic semiconductor.

The structure illustrated in FIG. 2A is known as a top-gate organic thin-film transistor as the gate is located on a top side of the device relative to a substrate. Alternatively, it is also known to provide the gate on a bottom side of the device to form a so-called bottom-gate organic thin-film transistor.

An example of a bottom-gate organic thin-film transistor is shown in FIG. 2B, which is not drawn to any scale. In order to show more clearly the relationship between the structures illustrated in FIGS. 2A and 2B, like reference numerals have been used for corresponding parts.

The bottom-gate structure illustrated in FIG. 2B, which is not drawn to any scale, comprises a gate electrode 215 deposited on a substrate 201 with an insulating layer 213 of dielectric material deposited thereover. Source and drain electrodes 203, 205 are deposited over the insulating layer 213 of dielectric material. The source and drain electrodes 203, 205 are spaced apart with a channel region 207 located therebetween over the gate electrode. An organic semiconductor layer 211 in the channel region 207 is in electrical contact with the surface modification layer 209, and may extend over at least a portion of the source and drain electrodes 203, 205.

The layer in contact with the surface modification layer in any of FIGS. 1A-2B may have a HOMO of no more than 5.8 eV, optionally in the range of 5.3-5.7 eV, optionally in the range 5.3-5.4 eV. The HOMO level may be measured by photoelectron spectroscopy.

In FIGS. 1 and 2, the surface modification layer 104, 209 is illustrated as being present on an upper face only of the electrode on which it is present. However, it will be appreciated that the surface modification layer may partially or fully cover one or more that one face of an exposed electrode surface. For example, in the case of an OTFT the surface modification layer may be provided on at least a face of the source and/or drain electrodes facing the channel. Upon deposition of a solution of the partially fluorinated fullerene over the channel and source and/or drain electrode surfaces, the partially fluorinated fullerene may selectively adhere to the exposed source and/or drain electrode faces, including faces facing the channel.

### Partially Fluorinated Fullerene

The fullerene of the partially fluorinated fullerene may be any carbon allotrope in the form of a hollow sphere or ellipsoid.

The fullerene may consist of carbon atoms arranged in 5, 6 and/or 7 membered rings, preferably 5 and/or 6 membered rings. C₆₀ Buckminster Fullerene is particularly preferred.

The partially fluorinated fullerene may have formula CₐF_{b} wherein b is in the range of 10-60, optionally 10-50, and a is more than b. Examples include C₆₀F₁₈, C₆₀F₂₀, C₆₀F₃₆, C₆₀F₄₈, C₇₀F₄₄, C₇₀F₄₆, C₇₀F₄₈, and C₇₀F₅₄. Partially fluorinated fullerenes and their synthesis are described in more detail in, for example, Andreas Hirsch and Michael Brettreich, “Fullerenes: Chemistry and Reactions”, 2005 Wiley-VCH Verlag GmbH & Co KGaA, and in “The Chemistry Of Fullerenes”, Roger Taylor (editor) Advanced Series in Fullerenes—Vol. 4.

The partially fluorinated fullerene may consist of carbon and fluorine only or may include other elements, for example halogens other than fluorine and/or oxygen.

The partially fluorinated fullerene may have a LUMO level in the range of about −4.0 or deeper, optionally −4.0 to −5.0 eV as measured by cyclic voltammetry relative to a Saturated Calomel Electrode (SCE) in acetonitrile using tetraethylammonium perchlorate as supporting electrolyte, and assuming the Fermi energy level of SCE as 4.94 eV.

### Surface Modification Layer

The partially fluorinated fullerene may be deposited by any method known to the skilled person, including deposition from a solution of the partially fluorinated fullerene in at least one solvent followed by evaporation of the at least one solvent, and thermal evaporation of the partially fluorinated fullerene.

Solution processing methods include coating and printing methods. Exemplary coating methods include spin coating, dip-coating, slot die coating and doctor blade coating. Exemplary printing methods include inkjet printing, flexographic printing and gravure printing.

Suitable solvents for partially fluorinated fullerenes include benzenes and naphthalenes substituted with one or more substituents selected from: halogen, for example chlorine; C₁₋₁₀ alkyl, for example methyl; and C₁₋₁₀ alkoxy, for example methoxy. Exemplary solvents include mono- or poly-chlorinated benzenes or naphthalenes, for example dichlorobenzene and 1-chloronaphthalene; benzene or naphthalene substituted with one or more methyl groups, for example toluene, o-xylene, m-xylene, 1-methylnaphthalene; and solvents substituted with more than one of a halogen, C₁₋₁₀ alkyl and C₁₋₁₀ alkoxy, for example 4-methylanisole.

The thickness of the partially fluorinated film may be no more than 10 nm, optionally less than 5 nm, optionally a monolayer.

Without wishing to be bound by any theory, it is believed that the partially fluorinated fullerene forms a charge-transfer complex at the surface of the electrode material onto which it is deposited, resulting in an increase in workfunction at the resultant surface.

At lower thicknesses, in particular at monolayer thickness, substantially all of the partially fluorinated fullerene deposited onto the electrode surface may form a charge-transfer complex, in which case substantially all of the organic semiconductor/surface modification layer interface may be an interface between the charge-transfer complex and the organic semiconductor.

At higher thicknesses, the surface modification layer may include a charge-transfer complex layer part, for example a charge-transfer complex monolayer and, overlying the charge-transfer complex layer, a remainder layer part of fullerene that has not formed a charge transfer complex. Remaining fullerene that has not formed a charge-transfer complex may dope the organic semiconductor overlying the surface modification layer. Heating the organic semiconductor layer, which may take place after and/or during device manufacture, may increase the extent of doping of the organic semiconductor layer, particularly if the organic semiconductor material of the organic semiconductor layer is an amorphous material, for example a polymer. A heating temperature may be at least 160° C. Heating the organic semiconductor layer at a temperature above a glass transition temperature of the organic semiconductor material may increase the extent of doping.

Without wishing to be bound by any theory, it is believed that the presence of a substantial amount of partially fluorinated fullerene in the surface modification layer that has neither formed part of a charge-transfer complex nor doped the organic semiconductor may be detrimental to device performance. Accordingly, a surface modification layer having a thickness of no more than 10 nm may contain sufficient partially fluorinated fullerene to allow formation of a charge-transfer complex layer and optionally allow for doping of the organic semiconductor material by any remaining fullerene, without containing an amount of fullerene that may be detrimental to device performance.

Thickness of the surface modification layer may be controlled by evaporating a controlled amount of the partially fluorinated fullerene onto the surface of the electrode to be modified.

The present inventors have surprisingly found that the thickness of the surface modification layer may be controlled by deposition of the partially fluorinated fullerene from solution by, for example by one or more of:
(i) depositing a solution of a selected concentration of the partially fluorinated fullerene onto the surface of the electrode to be modified, and/or
(ii) depositing a solution of the partially fluorinated fullerene onto the surface of the electrode to be modified and then removing the solution from the surface of the electrode before substantially all of the solvent has evaporated. Exemplary removal methods include rinsing using a rinsing solvent; blowing the solution off the electrode; and scraping the solution of the electrode. A solvent with a high boiling point may be used such that evaporation of the solvent, and associated precipitation of the partially fluorinated fullerene from solution, is slow. The solvent may have a boiling point of at least 200° C.

Formation of a thin (optionally no more than 10 nm) film of partially fluorinated fullerene may be obtained from a solution having a fluorinated fullerene concentration less than 1 wt %, optionally less than 0.5 wt %, optionally less than 0.25 wt %.

The partially fluorinated fullerene may selectively bind to the at least one electrode in which case the partially fluorinated fullerene may be applied over the at least one electrode using an indiscriminate deposition method, and partially fluorinated fullerene that does not fall on the at least one electrode surface may be removed by washing with a suitable solvent. For example, in the case of an OTFT the partially fluorinated fullerene may be deposited from solution onto both a surface of the source and drain electrodes and a surface of the channel (which may be, for example, glass or a treated glass surface), and partially fluorinated fullerene in the channel may be washed away.

### Electrode Materials

The electrode material that the partially fluorinated fullerene is deposited onto may include a conductive electrode material wherein the LUMO level of the partially fluorinated fullerene is deeper than the workfunction of the conductive electrode material (for the avoidance of any doubt, “deeper” as used herein in the context of an energy level means further from vacuum level”).

Exemplary conductive electrode materials include silver, gold, nickel, copper, indium-tin oxide, and fluorinated tin oxide. The electrode may be formed from these materials alone or mixtures or alloys of the conductive electrode material and one or more further materials, for example the silver-palladium-copper alloy APC.

### OTFT Organic Semiconductor

In the case where the electronic device is an OTFT, exemplary OTFT organic semiconductors include small molecule (i.e. non-polymeric) compounds having a core of at least three fused rings wherein each ring is independently selected from aromatic rings and heteroaromatic rings that may each individually be unsubstituted or substituted with one or more substituents, optionally with one or more solubilising substituents.

Small molecule compounds may be compounds having a polydispersity of 1, and may include dendrimers and oligomers (for example dimers, trimers, tetramers and pentamers).

Solubilising substituents may be substituents that increase solubility of the organic semiconductor in an organic solvent, for example a non-polar organic solvent, as compared to an unsubstituted organic semiconductor.

Optionally, the first small molecule organic semiconductor is selected from compounds of formulae (I)-(V) as described above.

Ar³, Ar⁴, Ar⁵, Ar⁶, Ar⁷, Ar⁸ and Ar⁹ may each independently be unsubstituted or substituted with one or more substituents.

Preferred substituents are X, which in each occurrence may be the same or different and may be selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups that may be unsubstituted or substituted with one, two or three alkyl groups having from 1 to 8 carbon atoms, silylethynyl groups that may be unsubstituted or substituted with one, two or three alkyl groups having from 1 to 8 carbon atoms and alkenyl groups having from 2 to 12 carbon atoms.

Optionally, at least one of Ar³, Ar⁴, Ar⁵, Ar⁶, Ar⁷, Ar⁸ and Ar⁹ comprises a 5- to 7-membered heteroaryl group containing from 1 to 3 sulfur atoms, oxygen atoms, selenium atoms and/or nitrogen atoms

The OTFT organic semiconductor may be an electron-rich compound, for example a compound comprising fused thiophene repeat units. Optionally, Ar³, Ar⁴, Ar⁵, Ar⁶, Ar⁷, Ar⁸ and Ar⁹ are each independently selected from phenyl and thiophene and wherein at least one of Ar³, Ar⁴, Ar⁵, Ar⁶, Ar⁷, Ar⁸ and Ar⁹ is thiophene.

The OTFT organic semiconductor may be selected from compounds of formulae (VI), (VII), (VIII), (IX) and (X):

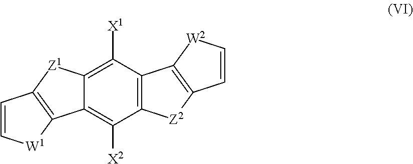

wherein X¹ and X² may be the same or different and are selected from substituents X as described above; Z¹ and Z² are independently S, O, Se or NR⁴; and W¹ and W² are independently S, O, Se, NR⁴ or —CR⁴═CR⁴—, where R⁴ is H or a substituent selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms;

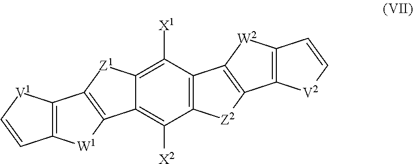

wherein X¹ and X² are as described with reference to formula (VI), Z¹, Z², W¹ and W² are as described with reference to formula (VI) and V¹ and V² are independently S, O, Se or NR⁵ wherein R⁵ is H or a substituent selected from the group consisting of substituted or unsubstituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms;

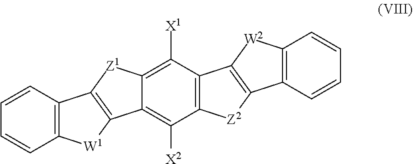

wherein X¹ and X², Z¹, Z², W¹ and W² are as described with reference to formula (VI).

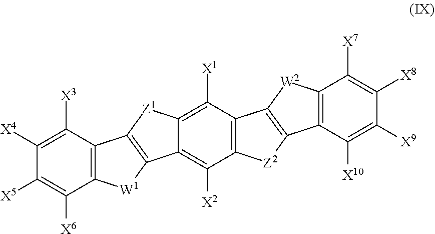

wherein Z¹, Z², W¹ and W² are as described with reference to formula (VI) and X¹-X¹⁰, which may be the same or different, are selected from substituents X as described above;

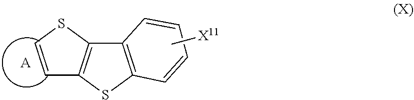

wherein A is a phenyl group or a thiophene group, said phenyl group or thiophene group optionally being fused with a phenyl group or a thiophene group which can optionally be fused with a group selected from a phenyl group, a thiophene group and a benzothiophene group, any of said phenyl, thiophene and benzothiphene groups being unsubstituted or substituted with at least one group of formula X¹¹; and

each group X¹¹ may be the same or different and is selected from substituents X as described above, and preferably is a group of formula CₙH_{2n±1} wherein n is an integer of from 1 to 20.

In the compound of formula (X), A is optionally selected from:

a thiophene group that is fused with a phenyl group substituted with at least one group of formula X¹¹; or

a phenyl group that may be unsubstituted or substituted with at least one group of formula X¹¹, said phenyl group further optionally being fused with a thiophene group which can be unsubstituted or substituted with at least one group of formula X¹¹ and/or fused with a benzothiophene group, said benzothiphene group being unsubstituted or substituted with at least one group of formula X¹¹, wherein X¹¹ is a group of formula CₙH₂ₙ₊₁ wherein n is an integer of from 1 to 16.

Compounds of formula (X) include the following:

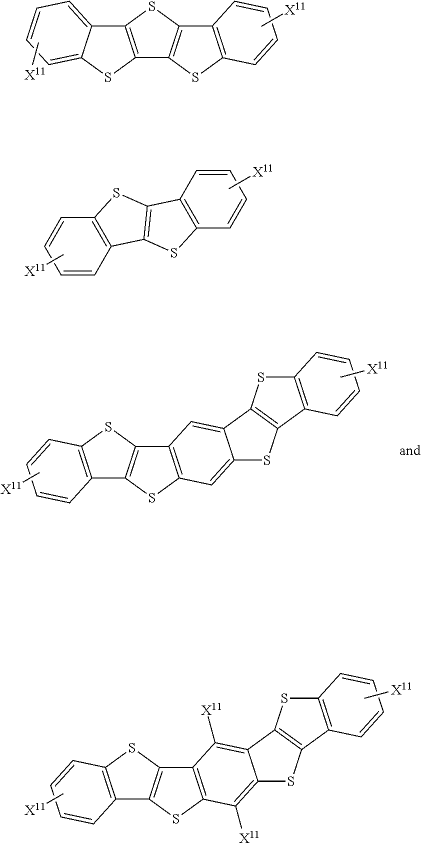

wherein X¹¹ is a group of formula CₙH₂₊₁ wherein n is an integer of from 1 to 16.

A preferred compound of formula (III) is pentacene substituted with one or more tri(C₁₋₁₀ alkyl)silylethynyl groups. Preferably, a tri(C₁₋₁₀ alkyl)silylethynyl substituent is provided in the 6- and 13-positions of pentacene. An exemplary substituted pentacene is 6,13-(tri-isopropyl-silylethynyl)pentacene (“TIPS pentacene”):

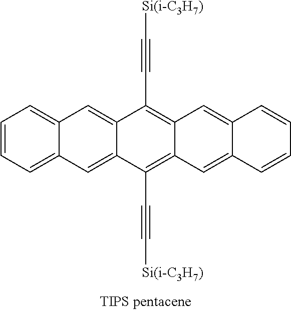

The one or more substituents of the OTFT organic semiconductor, for example substituents X and X¹-X¹¹ as described above, may be provided on: (a) one or both of the monocyclic aromatic or heteroaromatic rings at the end(s) of the organic semiconductor core; (b) on one or more of the monocyclic aromatic or heteroaromatic ring or rings that are not at the ends of the organic semiconductor core; or on both of (a) and (b).

The organic semiconducting layer may consist essentially of a small molecule organic semiconductor, or may comprise a blend of the small molecule organic semiconductor and one or more further materials. The organic semiconducting layer may comprise a blend of a small molecule organic semiconductor and a semiconducting or insulating polymer. Exemplary semiconducting polymers are described in more detail below.

The organic semiconductor may be deposited by any method known to the skilled person, for example by evaporation or, in the case of a soluble organic semiconductor, from a solution in one or more solvents.

### Polymers

The organic semiconductor layer of the organic electronic device may contain one or more semiconducting polymers.

The organic semiconductor layer may consist essentially of a semiconducting polymer or it may contain one or more further materials.

In one preferred embodiment, the organic electronic device is an OTFT and the organic semiconductor layer is selected from one of: a layer consisting essentially of a semiconducting polymer; a layer comprising a semiconducting polymer wherein the only semiconducting material is the semiconducting polymer; and a layer comprising a blend of a semiconducting polymer and a small molecule organic semiconductor, for example a small molecule organic semiconductor as described above.

In another preferred embodiment, the organic electronic device is an OLED and the organic semiconducting layer in contact with the surface modification layer is selected from one of: a hole-transporting layer comprising a hole-transporting polymer; a light-emitting layer comprising a light-emitting polymer that emits light during operation of the device; and a light-emitting layer comprising a semiconducting polymer and a light-emitting dopant wherein the light-emitting dopant emits light during operation of the device.

The semiconducting polymer may be a conjugated polymer. The semiconducting polymer may be a homopolymer or a co-polymer comprising two or more different repeat units.

A conjugated polymer may comprise repeat units selected from one or more of: substituted or unsubstituted (hetero)arylamine repeat units; substituted or unsubstituted heteroarylene repeat units; and substituted or unsubstituted arylene repeat units. The conjugated polymer may be a homopolymer or a copolymer comprising two or more different repeat units. An exemplary copolymer comprises one or more (hetero)arylamine repeat units, for example repeat units of formula (XI) described below, and one or more arylene repeat units, for example one or more fluorene and/or phenylene repeat units as described below.

Exemplary (hetero)arylamine repeat units may be selected from repeat units of formula (XI):

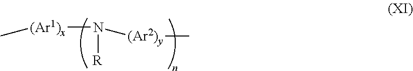

wherein Ar¹ and Ar² in each occurrence are independently selected from substituted or unsubstituted aryl or heteroaryl groups, n is greater than or equal to 1, preferably 1 or 2, R in each occurrence is H or a substituent, preferably a substituent, and x and y are each independently 1, 2 or 3.

Exemplary groups R include alkyl, Ar¹⁰, or a branched or linear chain of Ar¹⁰ groups, for example —(Ar¹⁰)ᵥ, wherein Ar¹⁰ in each occurrence is independently selected from aryl or heteroaryl and v is at least 1, optionally 1, 2 or 3.

Any of Ar¹, Ar² and Ar¹⁰ may independently be substituted with one or more substituents. Preferred substituents are selected from the group R³ consisting of:

alkyl wherein one or more non-adjacent C atoms may be replaced with O, S, substituted N, C═O and —COO— and one or more H atoms of the alkyl group may be replaced with F or aryl or heteroaryl which may be unsubstituted or substituted with one or more groups R⁸,

aryl or heteroaryl which may be unsubstituted or substituted with one or more groups R⁸,

NR⁹₂, OR⁹, SR⁹,

fluorine, nitro and cyano;

wherein each R⁸ is independently alkyl in which one or more non-adjacent C atoms may be replaced with O, S, substituted N, C═O and —COO— and one or more H atoms of the alkyl group may be replaced with F, and each R⁹ is independently selected from the group consisting of alkyl and aryl or heteroaryl which may be unsubstituted or substituted with one or more alkyl groups.

R may comprise a crosslinkable-group, for example a group comprising a polymerisable double bond such and a vinyl or acrylate group, or a benzocyclobutane group.

Any of the aryl or heteroaryl groups in the repeat unit of Formula (XI) may be linked by a direct bond or a divalent linking atom or group. Preferred divalent linking atoms and groups include O, S; substituted N; and substituted C.

Where present, substituted N or substituted C of R³, R⁸ or of the divalent linking group may independently in each occurrence be NR⁶ or CR⁶₂ respectively wherein R⁶ is alkyl or substituted or unsubstituted aryl or heteroaryl. Optional substituents for aryl or heteroaryl groups R⁶ may be selected from R⁸ or R⁹.

In one preferred arrangement, R is Ar¹⁰ and each of Ar¹, Ar² and Ar¹⁰ are independently unsubstituted or substituted with one or more C₁₋₂₀ alkyl groups.

Particularly preferred units satisfying Formula (XI) include units of Formulae 1-3:

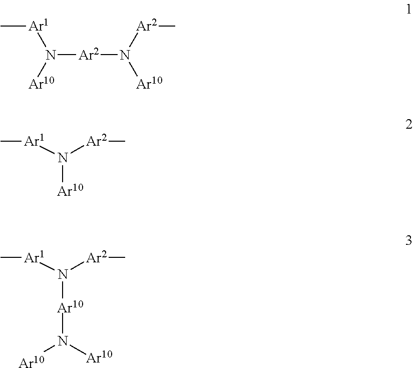

wherein Ar¹ and Ar² are as defined above; and Ar¹⁰ is unsubstituted or substituted aryl or heteroaryl. Where present, preferred substituents for Ar¹⁰ include substituents as described for Ar¹ and Ar², in particular alkyl and alkoxy groups.

Ar¹, Ar² and Ar¹⁰ are preferably phenyl, each of which may independently be substituted with one or more substituents as described above.

In another preferred arrangement, aryl or heteroaryl groups of formula (XI) are phenyl, each phenyl group being unsubstituted or substituted with one or more alkyl groups.

In another preferred arrangement, Ar¹, Ar² and Ar¹⁰ are phenyl, each of which may be substituted with one or more C₁₋₂₀ alkyl groups, and v=1.

In another preferred arrangement, Ar¹ and Ar² are phenyl, each of which may be substituted with one or more C₁₋₂₀ alkyl groups, and R is 3,5-diphenylbenzene wherein each phenyl may be substituted with one or more C₁₋₂₀ alkyl groups.

In another preferred arrangement, Ar¹, Ar² and Ar¹⁰ are phenyl, each of which may be substituted with one or more C₁₋₂₀ alkyl groups, n=1 and Ar¹ and Ar² are linked by O to form a phenoxazine group.

The polymer may comprise one, two or more different repeat units of formula (XI). For example, in the case of an OLED the polymer may comprise one repeat unit of formula (XI) to provide hole transport and another repeat unit of formula (XI) to provide light-emission.

The polymer comprising repeat units of formula (XI) may be a homopolymer or a copolymer comprising repeat units other than repeat units of formula (XI). The repeat units of formula (XI) may be provided in any amount, for example in the range of about 1 mol % to about 70 mol %. In the case where the polymer is used as a light-emitting material, the repeat units of formula (XI) may be present in an amount less than 50 mol %, for example less than 20 mol % or less than 10 mol %.

Exemplary arylene repeat units include fluorene, indenofluorene, and phenylene repeat units, each of which may optionally be substituted by, for example, alkyl or alkoxy.

Exemplary fluorene repeat units include repeat units of formula (XII):

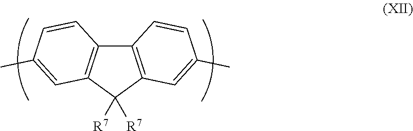

wherein the two groups R⁷, which may be the same or different, are each H or a substituent and wherein the two groups R⁷ may be linked to form a ring.

Each R⁷ is optionally selected from the group consisting of hydrogen; unsubstituted or substituted Ar¹⁰ or a linear or branched chain of Ar¹⁰ groups, wherein Ar¹⁰ is as described above with reference to formula (XI) and is preferably substituted or unsubstituted phenyl; and unsubstituted or substituted alkyl wherein one or more non-adjacent C atoms of the alkyl group may be replaced with O, S, substituted N, C═O and —COO—.

In the case where R⁷ comprises alkyl, optional substituents of the alkyl group include F, CN, nitro, and aryl or heteroaryl unsubstituted or substituted with one or more groups R⁸ wherein R⁸ is as described above with reference to formula (XI).

In the case where R⁷ comprises aryl or heteroaryl, each aryl or heteroaryl group may independently be substituted. Preferred optional substituents for the aryl or heteroaryl groups include one or more substituents R³ as described above with reference to formula (XI).

Optional substituents for the fluorene unit, other than substituents R⁷, are preferably selected from the group consisting of alkyl wherein one or more non-adjacent C atoms may be replaced with O, S, substituted N, C═O and —COO—; unsubstituted or substituted aryl, for example phenyl unsubstituted or substituted with one or more alkyl groups; unsubstituted or substituted heteroaryl; fluorine, cyano and nitro.

Where present, substituted N in repeat units of formula (XII) may independently in each occurrence be NR⁹ or NR⁶ wherein R⁶ and R⁹ are as described above with reference to formula (XI).

In one preferred arrangement, at least R⁷ comprises an unsubstituted or substituted C₁-C₂₀ alkyl or an unsubstituted or substituted aryl group, in particular phenyl substituted with one or more C₁₋₂₀ alkyl groups.

Repeat units of formula (XII) are optionally present in the polymer in an amount of at least 20 mol %, optionally at least 50 mol %, optionally more than 50 mol %.

Exemplary phenylene repeat units include repeat units of formula (XIII):

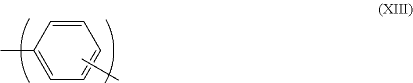

wherein the repeat unit of formula (XIII) may be substituted with one or more substituents R⁷ is as described above with reference to formula (XII). In one arrangement, the repeat unit is a 1,4-phenylene repeat unit.

The repeat unit of formula (XIII) may have formula (XIIIa), wherein R⁷ in each occurrence is a substituent and may be the same or different:

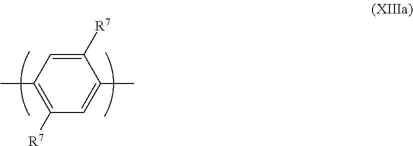

The polymer may be deposited from a solution in one or more solvents.

### OLED Hole Transporting Layer

An OLED may carry a hole transporting layer, for example as illustrated in the embodiment of FIG. 1B. The hole transporting layer may have a thickness in the range of 10-200 nm, optionally in the range of 10-100 nm.

The hole transporting layer may consist essentially of at least one hole-transporting material, or may comprise at least one hole transporting material and one or more further materials. Exemplary hole-transporting materials include small molecule arylamines, for example small molecules comprising triphenylamine, and polymers including homopolymers or copolymers comprising one or more repeat units of formula (XI).

The hole-transporting material of the hole transporting layer may be substantially undoped. If the substantially undoped hole-transporting material is deposited onto the surface modification layer, and if the surface modification layer contains partially fluorinated fullerene that has not formed a charge-transfer complex, then there may be some diffusion of this partially fluorinated fullerene from the surface modification layer which may result in some doping of the previously undoped hole-transporting material. If the hole-transporting material is doped then a dopant gradient within the hole transporting layer may be formed. This diffusion may occur in particular if the hole-transporting layer is heated following deposition, for example to crosslink or otherwise anneal the hole transporting layer.

The material used to form the hole transporting layer may have a HOMO level of 5.8 eV or shallower as measured by photoelectron spectroscopy, optionally in the range of 5.3-5.7 eV, optionally in the range 5.3-5.4 eV in order to facilitate injection of holes from the surface modification layer into the hole transporting layer.

The hole transporting material may be provided with crosslinkable groups, for example groups comprising a crosslinkable double bond or groups comprising benzocyclobutane. In the case of a hole-transporting polymer, the crosslinkable groups may be provided as substituents pendant from a backbone of the polymer. These crosslinkable groups may be crosslinked following deposition of the hole transporting material in order to form a substantially insoluble crosslinked hole-transporting layer.

Crosslinking may take place by thermal and/or UV treatment. A thermal treatment temperature may be up to about 220° C., optionally greater than about 160° C. and optionally greater than a glass transition temperature of the hole-transporting material. Thermal treatment time may be in the range of 5-120 minutes, optionally 10-60 minutes, and may depend on the treatment temperature.

The hole-transporting layer may be formed by any method known to the skilled person, including evaporation and deposition from a solution in one or more solvents followed by evaporation of the at least one solvent.

### OLED Light Emitting Layer

An OLED light-emitting layer may be in direct contact with the surface modification layer, as illustrated in FIG. 1A, or may be spaced apart from the surface modification layer by one or more intervening layers, for example a hole transporting layer as illustrated in the embodiment of FIG. 1B.

The OLED may comprise one or more than one light-emitting layers. For example, the OLED may comprise two or more light-emitting layers having emissions that combine to form white light.

Suitable light-emitting materials for use in an OLED light-emitting layer include small molecule, polymeric and dendrimeric materials, and compositions thereof. Suitable light-emitting polymers include conjugated polymers, for example unsubstituted or substituted poly(arylene vinylenes) such as poly(p-phenylene vinylenes) and unsubstituted or substituted polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23) 1737-1750 and references therein.

Polymers for use as light-emitting materials in devices according to the present invention may comprise a repeat unit selected from unsubstituted or substituted amine repeat units of formula (XI) and/or unsubstituted or substituted arylene or heteroarylene repeat units as described above, in particular fluorene repeat units of formula (XII) described above.

The light-emitting layer may consist of a light-emitting material alone, or may comprise this material in combination with one or more further materials. In particular, the light-emitting material may be blended with hole and/or electron transporting materials or alternatively may be covalently bound to hole and/or electron transporting materials as disclosed in for example, WO 99/48160.

Light-emitting copolymers may comprise a light-emitting region and at least one of a hole transporting region and an electron transporting region as disclosed in, for example, WO 00/55927 and U.S. Pat. No. 6,353,083. If only one of a hole transporting region and electron transporting region is provided then the electroluminescent region may also provide the other of hole transport and electron transport functionality—for example, an amine unit of formula (XI) as described above may provide both hole transport and light-emission functionality. A light-emitting copolymer comprising light-emitting repeat units and one or both of a hole transporting repeat units and electron transporting repeat units may provide said units in a polymer main-chain, as per U.S. Pat. No. 6,353,083, or in polymer side-groups pendant from the polymer backbone.

Suitable light-emitting materials may emit in the UV, visible and/or infra-red region of the electromagnetic spectrum. The OLED may contain one or more of red, green and blue light-emitting materials.

A blue light-emitting material may have photoluminescent spectrum with a peak wavelength in the range of less than or equal to 480 nm, such as in the range of 400-480 nm.

A green light-emitting material may have photoluminescent spectrum with a peak wavelength in the range of above 480 nm-560 nm.

A red light-emitting material may have photoluminescent spectrum with a peak wavelength in the range of above 560 nm-630 nm.

More than one light-emitting material may be used. For example, red, green and blue light-emitting dopants may be used to obtain white light emission.

The light emitting layer may comprise a host material and at least one light-emitting dopant. The host material may be a material as described above that would, in the absence of a dopant, emit light itself. When a host material and dopant are used in a device, the dopant alone may emit light. Alternatively, the host material and one or more dopants may emit light. White light may be generated by emission from multiple light sources, such as emission from both the host and one or more dopants or emission from multiple dopants.

In the case of a fluorescent light-emitting dopant the singlet excited state energy level (S₁) of the host material should be higher than that of the fluorescent light-emitting dopant in order that singlet excitons may be transferred from the host material to the fluorescent light-emitting dopant. Likewise, in the case of a phosphorescent light-emitting dopant the triplet excited state energy level (T₁) of the host material should be higher than that of the phosphorescent light-emitting dopant in order that triplet excitons may be transferred from the host material to the fluorescent light-emitting dopant. An exemplary host material is a polymer comprising one or more repeat units selected from formulae (XI), (XII) and (XIII).

Exemplary phosphorescent light-emitting dopants include unsubstituted or substituted complexes of formula (XIV):

ML¹_{q}L²ᵣL³ₛ (XIV)

wherein M is a metal; each of L¹, L² and L³ is a coordinating group; q is an integer; r and s are each independently 0 or an integer; and the sum of (a·q)+(b·r)+(c·s) is equal to the number of coordination sites available on M, wherein a is the number of coordination sites on L¹, b is the number of coordination sites on L² and c is the number of coordination sites on L³.

Heavy elements M induce strong spin-orbit coupling to allow rapid intersystem crossing and emission from triplet or higher states (phosphorescence). Suitable heavy metals M include d-block metals, in particular those in rows 2 and 3 i.e. elements 39 to 48 and 72 to 80, in particular ruthenium, rhodium, palladium, rhenium, osmium, iridium, platinum and gold. Iridium is particularly preferred.

Exemplary ligands L¹, L² and L³ include carbon or nitrogen donors such as porphyrin or bidentate ligands of formula (XV):

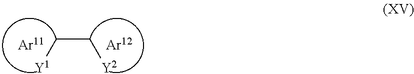

wherein Ar¹¹ and Ar¹² may be the same or different and are independently selected from unsubstituted or substituted aryl or heteroaryl; Y¹ and Y² may be the same or different and are independently selected from carbon or nitrogen; and Ar¹¹ and Ar¹² may be fused together. Ligands wherein Y¹ is carbon and Y² is nitrogen are particularly preferred.

Examples of bidentate ligands are illustrated below:

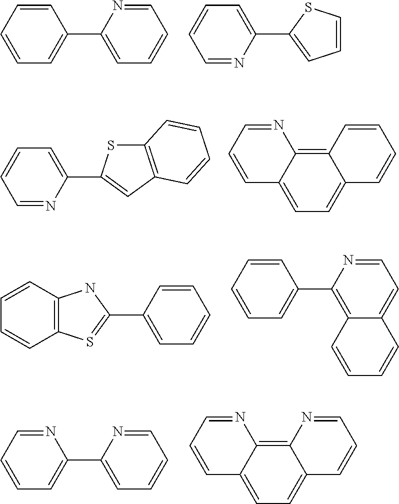

Each of Ar¹¹ and Ar¹² may independently carry one or more substituents. Two or more of these substituents may be linked to form a ring, for example an aromatic ring.

Other ligands suitable for use with d-block elements include diketonates, in particular acetylacetonate (acac); triarylphosphines and pyridine, each of which may be substituted.

Exemplary substituents include groups R³ groups R³ as described above with reference to Formula (XI). Particularly preferred substituents include fluorine or trifluoromethyl which may be used to blue-shift the emission of the complex, for example as disclosed in WO 02/45466, WO 02/44189, US 2002-117662 and US 2002-182441; alkyl or alkoxy groups, for example C₁₋₂₀ alkyl or alkoxy, which may be as disclosed in JP 2002-324679; carbazole which may be used to assist hole transport to the complex when used as an emissive material, for example as disclosed in WO 02/81448; bromine, chlorine or iodine which can serve to functionalise the ligand for attachment of further groups, for example as disclosed in WO 02/68435 and EP 1245659; and dendrons which may be used to obtain or enhance solution processability of the metal complex, for example as disclosed in WO 02/66552.

A light-emitting dendrimer may comprise a light-emitting core bound to one or more dendrons, wherein each dendron comprises a branching point and two or more dendritic branches. Preferably, the dendron is at least partially conjugated, and at least one of the branching points and dendritic branches comprises an aryl or heteroaryl group, for example a phenyl group. In one arrangement, the branching point group and the branching groups are all phenyl, and each phenyl may independently be substituted with one or more substituents, for example alkyl or alkoxy.

A dendron may have unsubstituted or substituted formula (XVI)

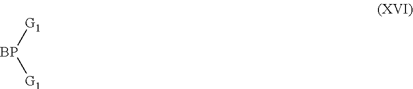

wherein BP represents a branching point for attachment to a core and G₁ represents first generation branching groups.

The dendron may be a first, second, third or higher generation dendron. G₁ may be substituted with two or more second generation branching groups G₂, and so on, as in the unsubstituted or substituted dendron of formula (XVIa):

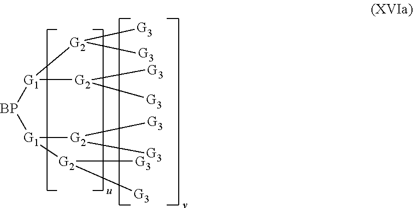

wherein u is 0 or 1; v is 0 if u is 0 or may be 0 or 1 if u is 1; BP represents a branching point for attachment to a core and G₁, G₂ and G₃ represent respective first, second and third generation dendron branching groups.

BP and/or any group G may be substituted with one or more substituents, for example one or more C₁₋₂₀ alkyl or alkoxy groups.

Where used, a light-emitting dopant may be present in an amount of about 0.05 mol % up to about 20 mol %, optionally about 0.1-10 mol % relative to their host material.

The light-emitting dopant may be physically mixed with the host material or it may be chemically bound to the host material in the same manner described above with respect to binding of the light-emitting dopant to the charge transporting material.

More than one light-emitting layer may be present.

The light-emitting layer may be patterned or unpatterned. An OLED comprising an unpatterned layer may be used an illumination source, for example. A white light emitting OLED is particularly suitable for this purpose. An OLED comprising a patterned layer may be, for example, an active matrix display or a passive matrix display. In the case of an active matrix display, a patterned electroluminescent layer may be used in combination with a patterned anode layer and an unpatterned cathode. In the case of a passive matrix display, the anode layer is formed of parallel stripes of anode material, and parallel stripes of electroluminescent material and cathode material arranged perpendicular to the anode material wherein the stripes of electroluminescent material and cathode material are typically separated by stripes of insulating material (“cathode separators”) formed by photolithography.

The material or materials of the light-emitting layer may be deposited by any method known to the skilled person, for example by evaporation or, in the case of soluble materials, from a solution in one or more solvents.

### Solution Processing

In the case where one or more layers of the organic electronic device are formed by solution processing, solution processing methods include coating and printing methods. Exemplary coating methods include spin coating, dip-coating, slot die coating and doctor blade coating. Exemplary printing methods include inkjet printing, flexographic printing and gravure printing.

Suitable solvents for soluble organic semiconductors, including soluble small molecule organic semiconductors and semiconducting polymers, may include benzenes substituted with one or more alkyl groups, for example one or more C₁₋₁₀ alkyl groups. Specific exemplary solvents include toluene and xylenes.

If a layer is formed by solution deposition onto an underlying layer that may be soluble in the solvent(s) used to deposit the layer then the underlying layer may be crosslinked prior to deposition of the solution. Alternatively or additionally, the solvent(s) for the solution may be selected from solvent(s) that do not dissolve the material(s) of the underlying layer.

### OLED Cathode

The cathode may be selected from materials that have a work function allowing injection of electrons into the light-emitting layer. Other factors influence the selection of the cathode such as the possibility of adverse interactions between the cathode and the materials of the light-emitting layer. The cathode may consist of a single material such as a layer of aluminium. Alternatively, it may comprise a plurality of metals, for example a bilayer of a low work function material and a high work function material such as calcium and aluminium as disclosed in WO 98/10621; elemental barium as disclosed in WO 98/57381, Appl. Phys. Lett. 2002, 81(4), 634 and WO 02/84759; or a thin layer of metal compound, in particular an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a work function of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode will comprise a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

In one arrangement, the surface of the cathode contacts a surface of the light-emitting layer. In another arrangement, one or more layers may be provided between the cathode and the light-emitting layer. For example, an organic electron-transporting layer may be provided between the light-emitting layer and the cathode.

### OTFT Gate Electrode

The gate electrode of an OTFT may be selected from a wide range of conducting materials for example a metal (e.g. gold), metal alloy, metal compound (e.g. indium tin oxide) or conductive polymer.

Thickness of the gate electrode may be in the region of 5-200 nm as measured by Atomic Force Microscopy (AFM).

### OTFT Gate Insulating Layer

The gate insulating layer comprises a dielectric material selected from insulating materials having a high resistivity. The dielectric constant, k, of the gate dielectric is typically around 2-3 although materials with a high value of k are desirable because the capacitance that is achievable for an OTFT is directly proportional to k, and the drain current is directly proportional to the capacitance. Thus, in order to achieve high drain currents with low operational voltages, OTFTs with thin dielectric layers in the channel region are preferred. The thickness of the insulating layer is preferably less than 2 micrometres, more preferably less than 500 nm.

The gate dielectric material may be organic or inorganic. Preferred inorganic materials include SiO₂, SiₓN_{y}, silicon oxynitride and spin-on-glass (SOG). Organic dielectric materials include fluorinated polymers such as polytetrafluoroethylene (PTFE), perfluoro cyclo oxyaliphatic polymer (CYTOP), perfluoroalkoxy polymer resin (PFA), fluorinated ethylene-propylene (FEP), polyethylenetetrafluoroethylene (ETFE), polyvinylfluoride (PVF), polyethylenechlorotrifluoroethylene (ECTFE), polyvinylidene fluoride (PVDF), polychlorotrifluoroethylene (PCTFE), perfluoro elastomers (FFKM) such as Kalrez® or Tecnoflon®, fluoro elastomers such as Viton®, Perfluoropolyether (PFPE) and a polymer of tetrafluoroethylene, hexafluoropropylene and vinylidene fluoride (THV).

Non-fluorinated organic polymer insulator materials may also be used and include polymers such as poly vinylalcohol (PVA), polyvinylpyrrolidone, polyvinylphenol, acrylates such as polymethylmethacrylate (PMMA) and benzocyclobutanes (BCBs) available from Dow Corning. The insulating layer may be formed from a blend of materials. A multi-layered structure may be used in place of a single insulating layer.

The gate dielectric material may be deposited by thermal evaporation under vacuum or by lamination techniques as are known in the art. Alternatively, the dielectric material may be deposited from solution using, for example, spin coating or ink jet printing techniques and other solution deposition techniques discussed above.

If the dielectric material is deposited from solution onto the organic semiconductor layer, it should not result in dissolution of the organic semiconductor layer. Likewise, the dielectric material should not be dissolved if the organic semiconductor layer is deposited onto it from solution. Techniques to avoid such dissolution include: use of orthogonal solvents, that is use of a solvent for deposition of the uppermost layer that does not dissolve the underlying layer; and crosslinking of the underlying layer.

### OTFT Further Layers

Other layers may be included in an OTFT, for example in order to reduce contact resistance and promote adhesion.

The surface of the channel region (that is, the region between the source and drain electrodes) may be provided with a monolayer comprising a material comprising a binding group and an organic group. Exemplary materials for such a monolayer include silanes, chloro- or alkoxy-silanes, for example a trichlorosilane substituted with a hydrocarbyl group selected from C₁₋₂₀ alkyl, phenyl and phenyl-C₁₋₂₀alkyl.

A material for modifying the surface of the channel region may selectively bind to the channel region such that the material may be applied over the channel and source and drain electrodes, and any material falling on the source and drain electrodes may be rinsed off.

### Encapsulation

OLEDs and OTFTs tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable, for example a plastic substrate or a substrate of alternating plastic and barrier layers or a laminate of thin glass and plastic as disclosed in EP 0949850. The substrate for may be opaque in the case of an OTFT or an OLED with a transparent cathode.

The device is preferably encapsulated with an encapsulant to prevent ingress of moisture and oxygen. Suitable encapsulants include a sheet of glass, films having suitable barrier properties such as silicon dioxide, silicon monoxide, silicon nitride or alternating stacks of polymer and dielectric as disclosed in, for example, WO 01/81649 or an airtight container as disclosed in, for example, WO 01/19142. In the case of a transparent cathode OLED device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### Examples

### General Method

A 0.03 weight % solution of a partially fluorinated fullerene selected from C60F36 and C60F48 was prepared.

A substrate carrying a layer of a conductive material was immersed in the solution for approximately 1 minute and then dried.

The work functions of the fullerene-treated substrates were measured by photoelectron spectroscopy using the AC-2 photoelectron spectrometer available from Riken Instruments Inc.

Measurements were performed in air, and produced plots of photoelectron yield vs. photon energy. The measurements were performed by probing a sample that is several square millimetres in area, and includes the following steps:
UV photons emitted from a deuterium lamp are monochromatized through the grating monochromator
The monocromatized UV photons at an intensity of 1002.8 nW are focused on the modified surface
The energy of the UV photons is increased from 4.2 eV to 6.2 eV, in steps of 0.05 eV
When the energy of the UV photons is higher than the threshold energy of photoemission of the sample material (i.e. the Ionisation Potential), photoelectrons are emitted from the sample surface
Photoelectrons emitted from the sample are detected and counted in the air by an open air counter
Photoemission threshold (Work function) is determined from the energy of an intersecting point between a background line and an extrapolated line of the square root of the photoelectric quantum yield.

### Examples 1 and 2

### Indium Tin Oxide

Indium tin oxide was treated according to the general method above, wherein the solution of the partially fluorinated fullerene was dried at 100° C. for 10 minutes in a glove box.

The results are summarized in Table 1 below:

TABLE 1

| Example | Fullerene | Work Function | Signal Gradient |
|---|---|---|---|
| Comparative | — | 4.85 eV | 15.3 |
| Example 1 - | | | |
| untreated ITO | | | |
| Comparative | — | 4.75 eV | 14.4 |
| Example 2 - ITO | | | |
| rised with 1,2- | | | |
| dichlorobenzene | | | |
| Example 1 | C₆₀F₃₆ | 5.66 eV | 12.1 |
| Example 2 | C₆₀F₄₈ | 5.33 eV | 13.0 |

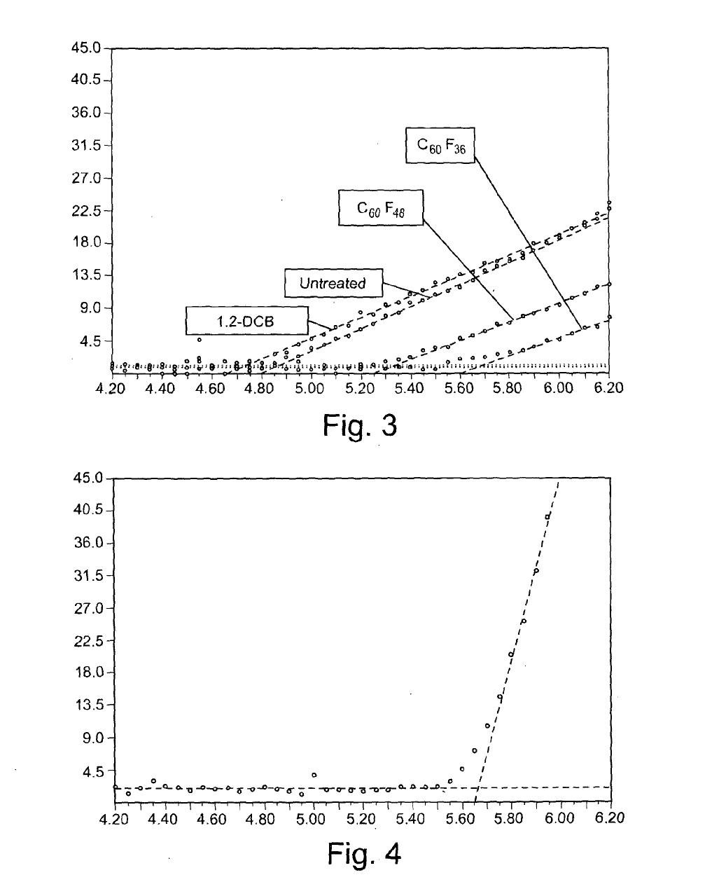

With reference to Table 1 and FIG. 3, treatment of the ITO surface with the solvent caused the measured work function to decrease slightly (i.e. move closer to vacuum).

In contrast, treatment of the ITO with a solution of fluorinated fullerene resulted in a substantial increase in work function.

The small change in signal gradient between ITO with and without a surface modification layer is indicative of a monolayer of fullerene.

### Examples 3-6

### Silver and Gold

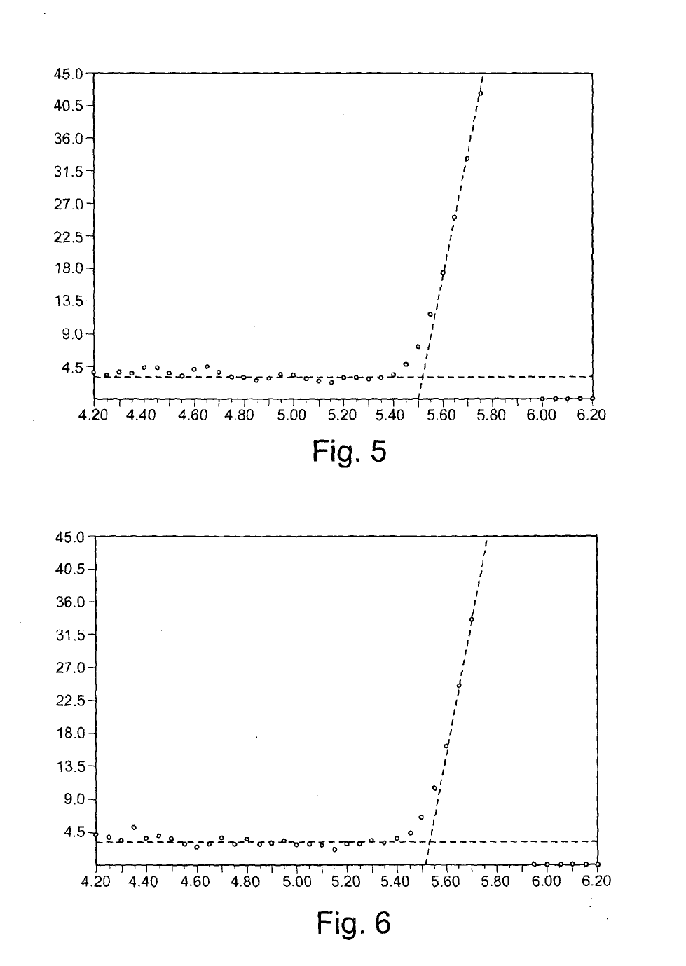

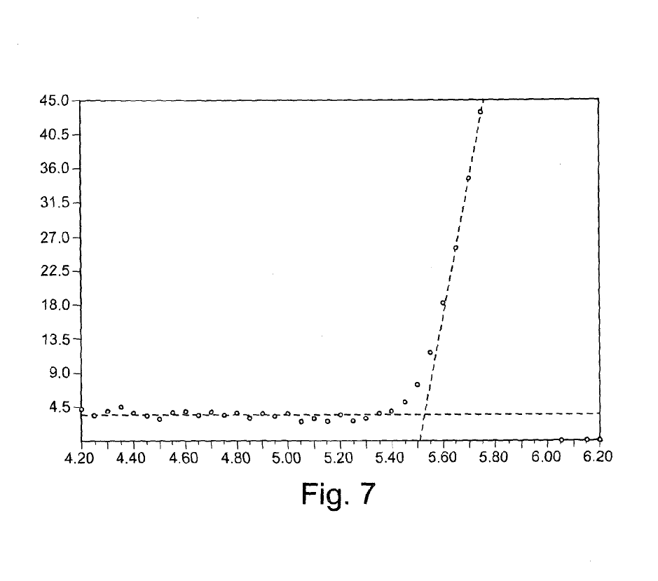

A process according to the general method was followed in which the conductive material was silver or gold and the solution of the partially fluorinated fullerene was blown dry with a nitrogen gun. The results are summarized in Table 2 below, and the AC-2 spectra of Examples 3-6 are shown in FIGS. 4-7 respectively.

TABLE 2

| | | | Work | Signal |
|---|---|---|---|---|
| Example | Fullerene | Metal | Function (eV) | Gradient |
| 3 | C₆₀F₃₆ | Ag | 5.7 | 128.5 |
| 4 | C₆₀F₄₈ | Ag | 5.52 | 169.91 |
| 5 | C₆₀F₃₆ | Au | 5.53 | 180.6 |
| 6 | C₆₀F₄₈ | Au | 5.53 | 178.85 |

### Examples 7-10 OLED Examples

Devices having the following structure were prepared:

### Example 7

### Hole-Only Device

ITO/Hole Transporting Layer/Gold Cathode

wherein the hole transporting layer was formed by spin-coating an o-xylene solution of a crosslinkable polymer comprising fluorene repeat units of formula (XII) and amine repeat units of (XI) and crosslinking the polymer to render it substantially insoluble; and the cathode consists of a layer of gold (100 nm).

The surface of the ITO was not treated with C₆₀F₃₆.

### Examples 8-10

### Surface-Treated ITO/Hole Transporting Layer/Light-Emitting Layer/Cathode

wherein the hole transporting layer was formed by spin-coating an o-xylene solution of a crosslinkable polymer comprising fluorene repeat units of formula (XII) and amine repeat units of (XI) and crosslinking the polymer to render it substantially insoluble; the light-emitting layer was formed by spin-coating an o-xylene solution of a polymer comprising fluorene repeat units of formula (XI) and amine repeat units of (XII); and the cathode consists of a first layer of a metal fluoride (2 nm), a second layer of aluminium (200 nm) and a third layer of silver (100 nm).

The surface-treated ITO was formed by treating ITO with a solution of C₆₀F₃₆ in 1,2-dichlorobenzene as described in Example 1, and wherein the solution is as described below:

| Example | Fullerene concentration (wt %) |
|---|---|
| 8 | 0.03 w % |
| 9 | 0.15 w % |
| 10 | 0.60 w % |

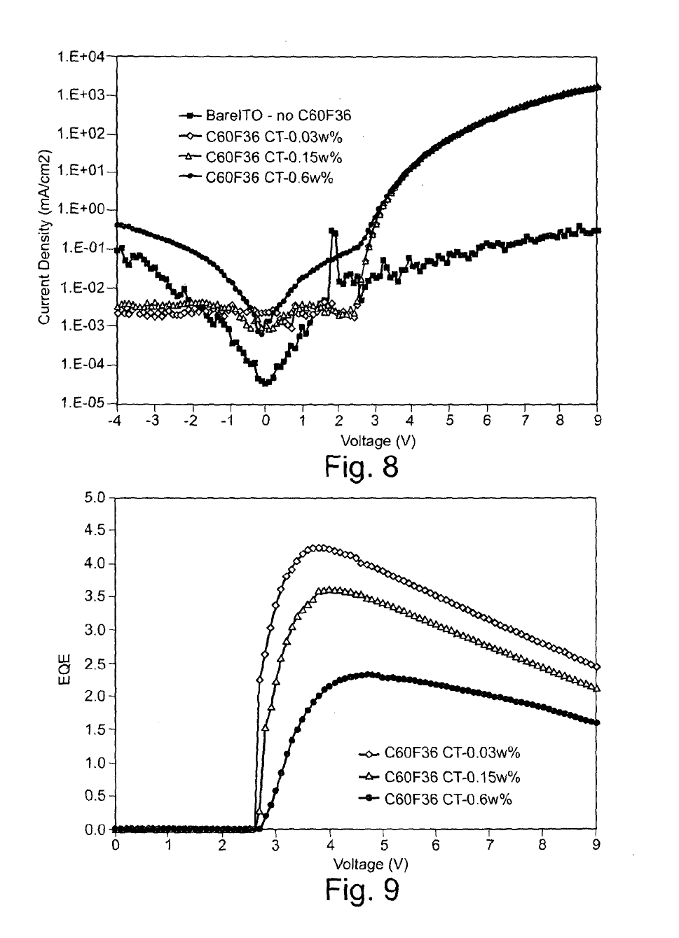

With reference to FIG. 8, the current density in the devices with bare ITO (example 7) is several orders of magnitude smaller as compared to the devices with C₆₀F₃₆-treated ITO. Without wishing to be bound by any theory, it is believed that the very low current densities in example 7 are predominantly due to the following two differences:
(1) The gold cathode in example 7 results in much less electron injection into the hole transporting polymer as compared to electron injection from the metal fluoride-aluminium-silver cathode into the light-emitting polymer layer in examples 8-10.
(2) The bare ITO anode in example 7 results in much less hole injection into the hole transporting polymer as compared to hole injection from the C60F36-treated ITO anodes into the hole transporting polymer in examples 8-10.

In contrast to the above, the different concentrations of C₆₀F₃₆ used for modifying the ITO anodes in the examples 8-10 result in very similar current densities.

With reference to FIG. 9, the external quantum efficiency decreases with increasing fullerene concentration of the solution used to treat the ITO surface. [The devices with bare ITO anode and gold cathode do not show any light emission—and are not shown here.]

Without wishing to be bound by any theory, it is believed that the thicker fullerene films that result from higher fullerene concentrations may be attributable to the observed reduction in quantum efficiency. Again, without wishing to be bound by any theory it is believed that this may be attributable to less of the hole transporting layer making contact with the ITO-fullerene charge-transfer complex formed at the surface of the anode at higher film thicknesses due to the presence of intervening, undoped fullerene. This undoped fullerene may dope the hole-transporting layer.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A method of forming an organic electronic device comprising the steps of:
forming a surface modification layer comprising a partially fluorinated fullerene on at least part of a surface of at least one electrode of the device by depositing a solution comprising the partially fluorinated fullerene and at least one solvent onto the electrode surface; and
forming an organic semiconductor layer comprising at least one organic semiconductor on the surface modification layer.

2. A method according to claim 1 wherein the surface modification layer is a monolayer.

3. (canceled)

4. A method according to claim 1 wherein the partially fluorinated fullerene is a partially fluorinated Buckminster fullerene.

5. A method according to claim 1 wherein the surface modification layer consists essentially of the partially fluorinated fullerene.

6. A method according to claim 1 wherein the organic semiconducting layer comprises a polymer.

7. (canceled)

8. A method according to claim 6 wherein the polymer comprises repeat units of formula (XI): 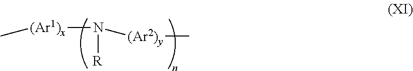
wherein Ar¹ and Ar² in each occurrence are independently selected from unsubstituted or substituted aryl or heteroaryl groups; n is greater than or equal to 1; R is H or a substituent; any of Ar¹, Ar² and R may be linked by a direct bond or linking group; and x and y are each independently 1, 2 or 3.

9. A method according to claim 6 wherein the polymer comprises one or more unsubstituted or substituted arylene repeat units.

10. A method according to claim 9 wherein the one or more substituted or unsubstituted arylene repeat units are selected from the group consisting of substituted or unsubstituted fluorene repeat units and substituted or unsubstituted phenylene repeat units.

11. (canceled)

12. A method according to claim 1 wherein the organic electronic device is an organic light-emitting device of which the at least one electrode is an anode, the organic light-emitting device further comprising a cathode and an organic region comprising the organic semiconductor layer between the anode and the cathode.

13. (canceled)

14. A method according to claim 12 wherein the organic semiconductor layer is a hole-transporting layer, the organic region further comprising an organic light-emitting layer.

15. (canceled)

16. A method according to claim 1 wherein the organic electronic device is an organic thin-film transistor of which the at least one electrode is a source and drain electrode, the organic thin-film transistor further comprising a channel between the source and drain electrodes wherein the organic semiconductor layer extends across the channel and contacts the surface modification layer; a gate electrode; and a gate dielectric between the organic semiconductor layer and the gate electrode.

17. A method according to claim 16 wherein at least one of the at least one organic semiconductors is selected from compounds of formulae (I)-(V): 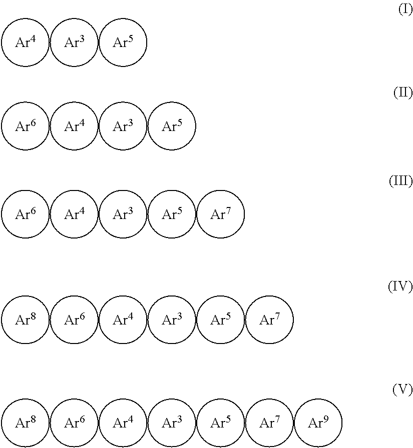
wherein Ar³, Ar⁴, Ar⁵, Ar⁶, Ar⁷, Ar⁸ and Ar⁹ are each independently selected from the group consisting of monocyclic aromatic rings and monocyclic heteroaromatic rings, and wherein Ar³, Ar⁴ and Ar⁵ may each optionally be fused to one or more further monocyclic aromatic or heteroaromatic rings.

18. A method according to claim 17 wherein the organic semiconducting layer further comprises a polymer.

19.-22. (canceled)

23. A method according to claim 1 wherein the solution consists essentially of the partially fluorinated fullerene and the at least one solvent.

24. A method according to claim 1 wherein the partially fluorinated fullerene is provided in the solution at a concentration of less than 1 weight %.

25. An organic thin film transistor comprising source and drain electrodes defining a channel therebetween; a surface-modification layer comprising a partially fluorinated fullerene on at least part of the surface of the source and drain electrodes; an organic semiconductor layer extending across the channel and in contact with the surface-modification layer; a gate electrode; and a gate dielectric between the organic semiconductor layer and the gate electrode.

26. An organic thin film transistor according to claim 25 wherein the surface-modification layer is substantially free of any organic semiconductor doped by the partially fluorinated fullerene.

27. An organic thin film transistor according to claim 25 wherein the surface-modification layer consists essentially of the partially fluorinated fullerene.

28. An organic thin film transistor according to claim 25 wherein the source and drain electrodes are selected from silver, gold, copper, nickel and alloys thereof.

29. (canceled)

30. A method of forming an organic thin film transistor according to claim 25, the method comprising the steps of:
depositing the partially fluorinated fullerene on the surface of the source and drain electrodes to form the surface modification layer; and
depositing the organic semiconductor on the surface modification layer.

31. (canceled)
